(19) United States
(12) Patent Application Publication
(10) Pub. No.: US 2013/0299809 A1
(43) Pub. Date: Nov. 14, 2013

(54) ORGANIC ELECTRONIC DEVICE FOR LIGHTING

(71) Applicant: Ying Wang, Wilmington, DE (US)

(72) Inventor: Ying Wang, Wilmington, DE (US)

(73) Assignee: E I DU PONT DE NEMOURS AND COMPANY, Willmington, DE (US)

(21) Appl. No.: 13/980,375

(22) PCT Filed: Mar. 8, 2012
(86) PCT No.: PCT/US2012/028235

§ 371 Date: Jul. 18, 2013

Related U.S. Application Data
(60) Provisional application No. 61/450,296, filed on Mar. 8, 2011.

(51) Int. Cl. H01L 51/52

(52) U.S. Cl. CPC H01L 51/52
USPC 257/40; 257/98

(57) ABSTRACT

There is provided an organic electronic device including a light-transmitting substrate, an enhancement film in direct contact with the substrate, an anode, a photoactive layer, and a cathode. The anode can be either a single layer or a multilayer. The single layer anode includes an alloy of a first metal having an electrical conductivity greater than 10⁵ Scm⁻¹ and a real refractive index less than 2.1 in the range of 380 to 780 nm. The multilayer electrode includes:
(a) layer M1 having a first thickness and including the first metal; and
(b) layer M2 having a second thickness and including a second metal, an alloy of the second metal, or a mixed metal oxide, where the second metal has an electrical conductivity less than 10⁵ Scm⁻¹.
   In the multilayer electrode, layer M1 is in physical contact with layer M2, and the first thickness is greater than the second thickness.

### RELATED APPLICATION DATA

This application claims priority under 35 U.S.C. §119(e) from U.S. Provisional Application No. 61/450,296, filed on Mar. 8, 2011, which is incorporated by reference herein in its entirety.

### BACKGROUND INFORMATION

1. Field of the Disclosure

This disclosure relates in general to organic electronic devices and particularly to devices used for lighting.

2. Description of the Related Art

In organic electronic devices, such as organic light emitting diodes (“OLED”), that make up OLED displays or OLED lighting devices, the organic active layer is sandwiched between two electrical contact layers. In an OLED, at least one of the electrical contact layers is light-transmitting, and the organic active layer emits light through the light-transmitting electrical contact layer upon application of a voltage across the electrical contact layers.

It is well known to use organic electroluminescent compounds as the active component in light-emitting diodes. Simple organic molecules, conjugated polymers, and organometallic complexes have been used. Devices frequently include one or more charge transport layers, which are positioned between a photoactive (e.g., light-emitting) layer and an electrical contact layer. A device can contain two or more contact layers. A hole transport layer can be positioned between the photoactive layer and the hole-injecting contact layer. The hole-injecting contact layer may also be called the anode. An electron transport layer can be positioned between the photoactive layer and the electron-injecting contact layer. The electron-injecting contact layer may also be called the cathode. Charge transport materials can also be used as hosts in combination with the photoactive materials.

There is a continuing need for devices with improved properties.

### SUMMARY

There is provided an organic electronic device comprising a light-transmitting substrate, an enhancement film in direct contact with the substrate, an anode, a photoactive layer, and a cathode, wherein the anode comprises one of (a) a single layer A1 and (b) a multilayer, wherein the single layer A1 comprises an alloy of a first metal having an electrical conductivity greater than 10⁵ Scm⁻¹ and a real refractive index less than 2.1 in the range of 380 to 780 nm; and the multilayer comprises:
(a) layer M1 having a first thickness and comprising the first metal; and
(b) layer M2 having a second thickness and comprising a material selected from the group consisting of a second metal, an alloy of the second metal, and a mixed metal oxide, where the second metal has an electrical conductivity less than 10⁵ Scm⁻¹;
wherein layer M1 is in physical contact with layer M2 and the first thickness is greater than the second thickness.

The foregoing general description and the following detailed description are exemplary and explanatory only and are not restrictive of the invention, as defined in the appended claims.

### BRIEF DESCRIPTION OF THE DRAWINGS

Embodiments are illustrated in the accompanying figures to improve understanding of concepts as presented herein.

FIG. 1 includes an illustration of one example of an organic electronic device.

FIG. 2 includes an illustration of an organic electronic device with a composite anode.

FIG. 3 includes another illustration of an organic electronic device with a composite anode.

FIG. 4 includes another illustration of an organic electronic device with a composite anode.

FIG. 5 includes another illustration of an organic electronic device with a composite anode.

FIG. 6 includes another illustration of an organic electronic device with a composite anode.

FIG. 7 includes another illustration of an organic electronic device with a composite anode,

FIG. 8 includes another illustration of an organic electronic device with a composite anode.

FIG. 9 includes another illustration of an organic electronic device with a composite anode.

FIG. 10 includes another illustration of an organic electronic device with a composite anode.

FIG. 11 includes another illustration of an organic electronic device with a composite anode.

FIG. 12 includes another illustration of an organic electronic device with a composite anode.

FIG. 13 includes another illustration of an organic electronic device with a composite anode.

FIG. 14 includes another illustration of an organic electronic device with a composite anode.

FIG. 15 includes the electroluminescence spectra of two comparative devices.

FIG. 16 includes the electroluminescence spectra of two new devices and a comparative device.

FIG. 17 includes the electroluminescence spectra of two comparative devices.

FIG. 18 includes the electroluminescence spectra of two new devices and a comparative device.

Skilled artisans appreciate that objects in the figures are illustrated for simplicity and clarity and have not necessarily been drawn to scale. For example, the dimensions of some of the objects in the figures may be exaggerated relative to other objects to help to improve understanding of embodiments.

### DETAILED DESCRIPTION

Conventional white OLED devices that are used for lighting applications are based on an indium tin oxide (“ITO”) anode. These devices can only emit about 20-25% of the photons through the substrate in forward directions. The rest of the photons are wasted, either trapped inside the device or waveguided out from the edge. Outcoupling enhancement methods have to be used to harvest the trapped photons. For lighting applications, the enhancement method has to be able to maintain the white light spectrum near the desired black body curve. Unfortunately, most of the outcoupling enhancement methods can only enhance one portion of the spectrum. To restore the spectrum to the desired white point, adjustment of the internal device structure and material composition have to be made which can result in reduced efficiency. The new electronic devices described herein have a device architecture with a combination of complementary features to enhance different parts of the spectrum to achieve a balanced white light. This new device has the additional advantage of allowing the independent optimization of material and device architecture from the optimization of outcoupling methods.

Many aspects and embodiments have been described above and are merely exemplary and not limiting. After reading this specification, skilled artisans appreciate that other aspects and embodiments are possible without departing from the scope of the invention.

Other features and benefits of any one or more of the embodiments will be apparent from the following detailed description, and from the claims. The detailed description first addresses Definitions and Clarification of Terms, followed by the Enhancement Film, the Anode, the Electronic Device, and Examples.

### 1. Definitions and Clarification of Terms

Before addressing details of embodiments described below, some terms are defined or clarified.

The term “blue” is intended to mean radiation that has an emission maximum at a wavelength in a range of approximately 400-500 nm.

The term “charge transport,” when referring to a layer, material, member, or structure is intended to mean such layer, material, member, or structure facilitates migration of such charge through the thickness of such layer, material, member, or structure with relative efficiency and small loss of charge. Hole transport materials facilitate positive charge migration electron transport materials facilitate negative charge migration. Although light-emitting materials may also have some charge transport properties, the term “charge transport layer, material, member, or structure” is not intended to include a layer, material, member, or structure whose primary function is light emission or light absorption.

The term “dopant” is intended to mean a material, within a layer including a host material, that changes the electronic characteristic(s) or the targeted wavelength(s) of radiation emission, reception, or filtering of the layer compared to the electronic characteristic(s) or the wavelengths) of radiation emission, reception, or filtering of the layer in the absence of such material. A dopant of a given color refers to a dopant which emits light of that color.

The term “green” is intended to mean radiation that has an emission maximum at a wavelength in a range of approximately 500-580 nm.

The term “hole injection” when referring to a layer, material, member, or structure, is intended to mean such layer, material, member, or structure facilitates injection and migration of positive charges through the thickness of such layer, material, member, or structure with relative efficiency and small loss of charge.

The term “host material” is intended to mean a material, usually in the form of a layer, to which a dopant may or may not be added. The host material may or may not have electronic characteristic(s) or the ability to emit, receive, or filter radiation. When a dopant is present in a host material, the host material does not significantly change the emission wavelength of the dopant material.

The term “particle size” is intended to mean the average of the sizes of all the particles. It is understood that the particles can have any shape, including circular, rectangular, polygonal, and irregular shapes.

The term “size” is intended to mean the diameter of a circular particle, the larger diagonal of a rectangular particle, or the diameter of a circle which would enclose a particle of any other shape, including irregular shapes.

The term “photoactive” is intended to mean a material that emits light when activated by an applied voltage (such as in a light emitting diode or chemical cell) or responds to radiant energy and generates a signal with or without an applied bias voltage (such as in a photodetector or a photovoltaic cell).

The term “red” is intended to mean radiation that has an emission maximum at a wavelength in a range of approximately 580-700 nm.

The term “refractive index” or “index of refraction” of a substance is a measure of the speed of light in that substance. It is expressed as a ratio of the speed of light in vacuum relative to that in the considered medium. In general, a refractive index is a complex number with both a real and imaginary part, where the imaginary part is sometimes called the extinction coefficient k. As used herein, the “real refractive index” refers to the real part of the complex number. The refractive index depends strongly on the wavelength of light.

The term “small molecule,” when referring to a compound, is intended to mean a compound which does not have repeating monomeric units. In one embodiment, a small molecule has a molecular weight no greater than approximately 2000 g/mol.

The term “substrate” is intended to mean a base material that can be either rigid or flexible and may be include one or more layers of one or more materials, which can include, but are not limited to, glass, polymer, metal or ceramic materials or combinations thereof. The substrate may or may not include electronic components, circuits, or conductive members.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus.

In this specification, unless explicitly stated otherwise or indicated to the contrary by the context of usage, where an embodiment of the subject matter hereof is stated or described as comprising, including, containing, having, being composed of or being constituted by or of certain features or elements, one or more features or elements in addition to those explicitly stated or described may be present in the embodiment. An alternative embodiment of the disclosed subject matter hereof, is described as consisting essentially of certain features or elements, in which embodiment features or elements that would materially alter the principle of operation or the distinguishing characteristics of the embodiment are not present therein. A further alternative embodiment of the described subject matter hereof is described as consisting of certain features or elements, in which embodiment, or in insubstantial variations thereof, only the features or elements specifically stated or described are present.

Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Also, use of “a” or “an” are employed to describe elements and components described herein. This is done merely for convenience and to give a general sense of the scope of the invention. This description should be read to include one or at least one and the singular also includes the plural unless it is obvious that it is meant otherwise.

Group numbers corresponding to columns within the Periodic Table of the elements use the “New Notation” convention as seen in the CRC Handbook of Chemistry and Physics, 81^{st} Edition (2000-2001).

Unless otherwise defined, all technical and scientific terms used herein have the same meaning as commonly understood by one of ordinary skill in the art to which this invention belongs. Although methods and materials similar or equivalent to those described herein can be used in the practice or testing of embodiments of the present invention, suitable methods and materials are described below. All publications, patent applications, patents, and other references mentioned herein are incorporated by reference in their entirety, unless a particular passage is cited in case of conflict, the present specification, including definitions, will control. In addition, the materials, methods, and examples are illustrative only and not intended to be limiting.

To the extent not described herein, many details regarding specific materials, processing acts, and circuits are conventional and may be found in textbooks and other sources within the organic light-emitting diode display, photodetector, photovoltaic, and semiconductive member arts.

### 2. Enhancement Film

In some embodiments, the enhancement film improves light outcoupling. In some embodiments, the enhancement film is selected from the group consisting of light-scattering films, textured films, prismatic films, and microlens arrays.

In some embodiments, the enhancement film is one which scatters light. In some embodiments, the enhancement film comprises a matrix having particulate material dispersed therein. In some embodiments, the matrix and particles have different refractive indices. In some embodiments, the particles have a higher refractive index than the matrix material. In some embodiments, the particles have a lower refractive index than the matrix material.

In some embodiments, the matrix is a polymeric film. Exemplary polymeric materials include, but are not limited to polyesters, polycarbonates, poly(meth)acrylates, polysiloxanes, polyvinyl chloride, polystyrene, polyestersulfone, polybutadiene, polyetherketone, polyurethane, copolymers thereof, and deuterated analogs thereof. In some embodiments, the polymeric film is selected from the group consisting of polymethylmethacrylate films, polycarbonate films, and polysiloxane films. The term “polysiloxane” refers to a polymer having at least one structural unit [R₂SiO]ₙ, where R is the same or different at each occurrence and is an organic group.

The particulate material can be organic or inorganic. Some exemplary organic particulate materials include, but are not limited to, poly(meth)acrylates, polystyrene, polycarbonate, and parylene. Some exemplary inorganic particulate materials include, but are not limited to, metal oxides, metal nitrides, metal silicates, metal titanates, metal aluminosilicates, and mixtures thereof.

In some embodiments, the particulate material has a refractive index greater than 1.9, as measured at 632.8 nm; in some embodiments, greater than 2.0; in some embodiments, greater than 2.3. In some embodiments, the particulate material is an inorganic material having a refractive index greater than 1.9, as measured at 632.8 nm. Some exemplary inorganic materials include, but are not limited to titanium oxides and silicides, zirconium oxides and silicides, aluminum nitride, silicon nitrides, niobium oxides, barium titanates, and mixtures thereof. In some embodiments, the inorganic particulate material is selected from the group consisting of TiO₂, ZrO₂, AlN, BaTiO₃, and mixtures thereof.

The enhancement film can have a thickness in the range of 0.1 microns to 5.0 mm. In some embodiments, the thickness is in the range of 0.5 microns to 1.0 mm. The particulate material can have a particle size that is less than the thickness of the film. In some embodiments, the particle size is in the range of 0.01 microns to 100 microns; in some embodiments, 0.1 microns to 10 microns. The particulate material is present in an amount of 0.1-80% by weight; in some embodiments, 0.5-50% by weight; in some embodiments, 1-20% by weight.

The enhancement films can be made by any method for forming a filled film. Such methods are well known in the art. In some embodiments, the enhancement film is formed directly on the substrate. In some embodiments, the enhancement film is formed separately and then applied to the substrate, for example, by lamination.

### 3. Anode

The anode comprises one of (a) a single layer A1 and (b) a bilayer, wherein the single layer A1 comprises an alloy of a metal having an electrical conductivity greater than 10⁵ Scm⁻¹ and a real refractive index less than 2.1 in the range of 380 to 780 nm; and the bilayer comprises:
(a) layer M1 having a first thickness and comprising the first metal; and
(b) layer M2 having a second thickness and comprising a materials selected from the group consisting of a second metal, an alloy of the second metal, and a mixed metal oxide, where the second metal has an electrical conductivity less than 10⁵ Scm⁻¹;
wherein layer M1 is in physical contact with layer M2 and the first thickness is greater than the second thickness.
   a. Single layer Anode

In some embodiments, the anode comprises a single layer A1. The single layer A1 comprises an alloy of a first metal, where the first metal has an electrical conductivity greater than 10⁵ Scm⁻¹ and a real refractive index less than 2.1 in the range of 380 to 780 nm. In some embodiments, the first metal has an electrical conductivity greater than 2×10⁵ Scm⁻¹.

In some embodiments, layer A1 consists essentially of an alloy of the first metal.

In some embodiments, the alloy is at least 60% by weight of the first metal; in some embodiments, at least 70% by weight; in some embodiments, at least 80% by weight; in some embodiments, at least 90% by weight; in some embodiments, at least 95% by weight.

In some embodiments, the first metal is selected from the group consisting of copper, silver, and gold.

In some embodiments, the first metal is copper, which has an electrical conductivity of 6.0×10⁵ Scm⁻¹ and a real refractive index of 0.25 to 1.2 in the range of 380 to 780 nm.

In some embodiments, the first metal is silver, which has an electrical conductivity of 6.3×10⁵ Scm⁻¹ and a real refractive index of 0.2 to 0.15 in the range of 380 to 780 nm.

In some embodiments, the first metal is gold, which has an electrical conductivity of 4.5×10⁵ Scm⁻¹ and a real refractive index in the range of 1.7 to 0.2 in the range of 380 to 780 nm.

In some embodiments, the alloy metal is selected from the group consisting of silver, gold, copper, nickel, palladium, germanium, and titanium.

In some embodiments, the anode comprises an alloy selected from the group consisting of silver/gold, silver/gold/copper, gold/nickel, gold/palladium, silver/germanium, silver/copper, silver/palladium, silver/nickel, and silver/titanium. In some embodiments, the anode consists essentially of an alloy selected from the group consisting of silver/gold, silver/gold/copper, gold/nickel, gold/palladium, silver/germanium, silver/copper, silver/palladium, silver/nickel, and silver/titanium.

In some embodiments, the single layer A1 has a thickness in the range of 5-50 nm; in some embodiments, 10-30 nm.

Layer A1 can be formed by any conventional deposition technique for forming layers, including vapor deposition, liquid deposition (continuous and discontinuous techniques), and thermal transfer. In some embodiments, layer A1 is formed by a vapor deposition process. Such processes are well known in the art.

b. Multilayer Anode

In some embodiments, the anode comprises a multilayer. The multilayer comprises
(a) layer M1 having a first thickness and comprising a first metal or an alloy of the first metal, where the first metal has an electrical conductivity greater than 10⁵ Scm⁻¹ and a real refractive index less than 2.1 in the range of 380 to 780 nm; and
(b) layer M2 having a second thickness and comprising a material selected from the group consisting of a second metal, an alloy of the second metal, and a mixed metal oxide, where the second metal has an electrical conductivity less than 10⁵ Scm⁻¹.
   Layer M1 is in physical contact with layer M2 and the first thickness is greater than the second thickness.

In some embodiments, layer M1 consists essentially of the first metal.

In some embodiments, layer M2 consists essentially of a material selected from the group consisting of the second metal, an alloy of the second metal, and an oxide of the second metal. In some embodiments, layer M2 consists essentially of the second metal.

In some embodiments, the ratio of M1 thickness to M2 thickness is at least 5:1; in some embodiments, at least 10:1.

In some embodiments, the first metal has a thermal conductivity that is greater than the thermal conductivity of the second metal.

In some embodiments, the first metal is selected from the group consisting of copper, silver, gold, and an alloy thereof.

In some embodiments, the first metal is copper, which has an electrical conductivity of 6.0×10⁵ Scm⁻¹, a real refractive index of 1.2 to 0.25 in the range of 380 to 780 nm, and a thermal conductivity of 4.01 watts/cm° C.

In some embodiments, the first metal is silver, which has an electrical conductivity of 6.3×10⁵ Scm⁻¹, a real refractive index of 0.2 to 0.15 in the range of 380 to 780 nm, and a thermal conductivity of 4.29 watts/cm° C.

In some embodiments, the first metal is gold, which has an electrical conductivity of 4.5×10⁵ Scm⁻¹, a real refractive index in the range of 1.7 to 0.2 in the range of 380 to 780 nm, and a thermal conductivity of 3.17 watts/cm° C.

In some embodiments, layer M1 consists essentially of copper, silver, or gold.

In some embodiments, layer M1 has a thickness in the range of 5-50 nm; in some embodiments, 10-30 nm.

In some embodiments, the second metal has a thermal conductivity less than 1.0 watts/cm° C. In some embodiments, the second metal has a heat of fusion that is greater than the heat of fusion of the first metal. In some embodiments, the second metal has a heat of fusion greater than 14 kJ/mol.

In some embodiments, the second metal is selected from the group consisting of chromium, nickel, palladium, titanium, and germanium.

In some embodiments, the second metal is chromium, which has an electrical conductivity of 7.7×10⁴ Scm⁻¹ and a thermal conductivity of 0.91 watts/cm° C.

In some embodiments, the second metal is nickel, which has an electrical conductivity of 1.4×10⁵ Scm⁻¹ and a thermal conductivity of 0.90 watts/cm° C.

In some embodiments, the second metal is palladium, which has an electrical conductivity of 9.5×10⁴ Scm⁻¹ and a thermal conductivity of 0.72 watts/cm° C.

In some embodiments, the second metal is titanium, which has an electrical conductivity of 2.3×10⁴ Scm⁻¹ and a thermal conductivity of 0.22 watts/cm° C.

In some embodiments, the second metal is germanium, which has an electrical conductivity of 0 Scm⁻¹ and a thermal conductivity of 0.60 watts/cm° C.

In some embodiments, layer M2 consists essentially of a metal selected from the group consisting of chromium, nickel, palladium, titanium, and germanium.

In some embodiments, layer M2 comprises a mixed metal oxide. In some embodiments, the mixed metal oxide has one or more metals selected from the group consisting of aluminum, indium, tin, and zirconium.

In some embodiments, layer M2 comprises indium-tin-oxide, indium-zinc-oxide, aluminum-tin-oxide, aluminum-zinc-oxide, or zirconium-tin-oxide. In some embodiments, layer M2 consists essentially of a material selected from the group consisting of indium-tin-oxide, indium-zinc-oxide, aluminum-tin-oxide, aluminum-zinc-oxide, and zirconium-tin-oxide.

In some embodiments, layer M2 comprises a material selected from the group consisting of chromium, nickel, palladium, titanium, germanium, and indium tin oxide. In some embodiments, layer M2 consists essentially of a material selected from the group consisting of chromium, nickel, palladium, titanium, germanium, and indium tin oxide.

In some embodiments, layer M2 has a thickness in the range of 0.1-5 nm; in some embodiments, 0.5-5 nm.

Layers M1 and M2 can be formed by any conventional deposition technique for forming layers, including vapor deposition, liquid deposition (continuous and discontinuous techniques), and thermal transfer. In some embodiments, layers M1 and M2 are formed by a vapor deposition process. Such processes are well known in the art.

c. Additional Layers

The anode may optionally include one or more of a second layer M2, a layer M3, and a layer M4.

Layer M3 is a conductive inorganic layer which is at least partially transmissive to visible light. In some embodiments, layer M3 comprises indium-tin-oxide, indium-zinc-oxide, aluminum-tin-oxide, aluminum-zinc-oxide, or zirconium-tin-oxide. In some embodiments, layer M3 consists essentially of a material selected from the group consisting of indium-tin-oxide, indium-zinc-oxide, aluminum-tin-oxide, aluminum-zinc-oxide, and zirconium-tin-oxide. In some embodiments, layer M3 has a thickness in the range of 30-200 nm; in some embodiments, 50-150 nm.

Layer M3 can be formed by any conventional deposition technique for forming layers, including vapor deposition, liquid deposition (continuous and discontinuous techniques), and thermal transfer. In some embodiments, layer M3 is formed by a vapor deposition process. Such processes are well known in the art.

Layer M4 comprises an organic hole injection material. Hole injection materials may be polymers, oligomers, or small molecules. Examples of hole injection materials include, but are not limited to, conductive polymers doped with polymeric protonic acids, such as polyaniline (PANE) or polyethylenedioxythiophene (PEDOT) doped with poly(styrenesulfonic acid), poly(2-acrylamido-2-methyl-1-propanesulfonic acid), and the like; small molecules such as tetrafluorotetracyanoquinodimethane, perylene-3,4,9,10-tetracarboxylic-3,4,9,10-dianhydride, perylene-3,4,9,10-tetracarboxylic-3,4,9,10-diimide, naphthalene tetracarboxylic diimide, and hexaazatriphenylene hexacarbonitrile. In some embodiments, the hole injection material is a conducting polymer doped with a colloid-forming polymeric sulfonic acid. Such materials have been described in, for example, published U.S. patent applications US 2004/0102577, US 2004/0127637, and US 2005/0205860, and published POT application WO 2009/018009.

In some embodiments, layer M4 comprises a material selected from the group consisting of hexaazatriphenylene hexacarbonitrile and a conducting polymer doped with a colloid-forming polymeric sulfonic acid.

In some embodiments, layer M4 consists essentially of a material selected from the group consisting of hexaazatriphenylene hexacarbonitrile and a conducting polymer doped with a colloid-forming polymeric sulfonic acid.

In some embodiments, layer M4 has a thickness in the range of 10-300 nm in some embodiments, 50-200 nm.

Layer M4 can be formed by any conventional deposition technique, including vapor deposition, liquid deposition (continuous and discontinuous techniques), and thermal transfer. Continuous liquid deposition techniques, include but are not limited to, spin coating, gravure coating, curtain coating, dip coating, slot-die coating, spray coating, and continuous nozzle coating. Discontinuous liquid deposition techniques include, but are not limited to, ink jet printing, gravure printing, and screen printing.

When the single layer A1 is present, the anode may have any combination of the layers shown below in the order given.
M3/M2/A1/M2/M4
   provided that at least A1 is present.

When a bilayer of M1 and M2 is present, the anode may have any combination of the layers shown below in the order given.
M3/M2/M1/M2/M4
   provided that at least one M1 layer and one M2 layer are present.

In some embodiments, there may be any combination of the following:
(i) layer M1 consists essentially of copper, silver, gold, or an alloy thereof;
(ii) layer M2 consists essentially of chromium, nickel, palladium, titanium, germanium, an alloy of chromium, an alloy of nickel, an alloy of palladium, an alloy of titanium, an alloy of germanium, an oxide of chromium, an oxide of nickel, an oxide of palladium, an oxide of titanium, an oxide of germanium, indium-tin-oxide, indium-zinc-oxide, aluminum-tin-oxide, aluminum-zinc-oxide, or zirconium-tin-oxide;
(iii) the ratio of M1 thickness to M2 thickness is at least 5:1;
(iv) the first metal has a thermal conductivity that is greater than the thermal conductivity of the second metal.
(v) layer M1 has a thickness in the range of 5-50 nm;
(vi) the second metal has a thermal conductivity less than 1.0 watts/cm° C.;
(vii) the second metal has a heat of fusion that is greater than the heat of fusion of the first metal.
(viii) the second metal has a heat of fusion greater than 14 kJ/mol;
(ix) layer M2 has a thickness in the range of 0.1-5 nm;
(x) layer M3 is present and consists essentially of indium-tin-oxide, indium-zinc-oxide, aluminum-tin-oxide, aluminum-zinc-oxide, and zirconium-tin-oxide.
(xi) layer M3 has a thickness in the range of 30-200 nm;
(xii) layer M4 is present and consists essentially of a material which is hexaazatriphenylene hexacarbonitrile or a conducting polymer doped with a colloid-forming polymeric sulfonic acid;
(xiii) layer M4 has a thickness in the range of 10-300 nm.

### 4. Electronic Device

Organic electronic devices that may benefit from having the architecture as described herein include, but are not limited to, (1) devices that convert electrical energy into radiation (e.g., a light-emitting diode, light emitting diode display, lighting device, luminaire, or diode laser), (2) devices that detect signals through electronics processes (e.g., photodetectors, photoconductive cells, photoresistors, photoswitches, phototransistors, phototubes, IR detectors, biosensors), (3) devices that convert radiation into electrical energy, (e.g., a photovoltaic device or solar cell), and (4) devices that include one or more electronic components that include one or more organic semi-conductor layers (e.g., a transistor or diode). In particular, the architecture can be used for OLED lighting devices.

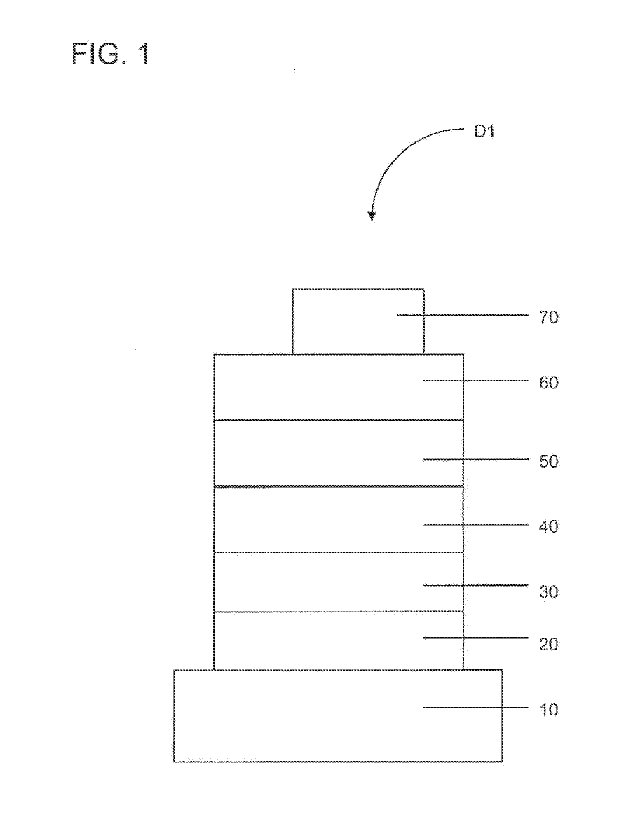

OLED devices generally include a photoactive layer between two electrical contact layers, which are an anode and a cathode. A typical device structure is illustrated schematically in FIG. 1. Device D1 includes substrate 10, anode 20, optional hole transport layer 30, photoactive layer 40, optional electron transport layer 50, optional electron injection layer 60, and cathode 70. In addition, a hole injection layer (not shown) may be present between the anode and the hole transport layer. For lighting devices, the photoactive layer is not pixellated. It should be noted that in all the figures the layers are not drawn to scale and the relative thicknesses of the layers are not shown.

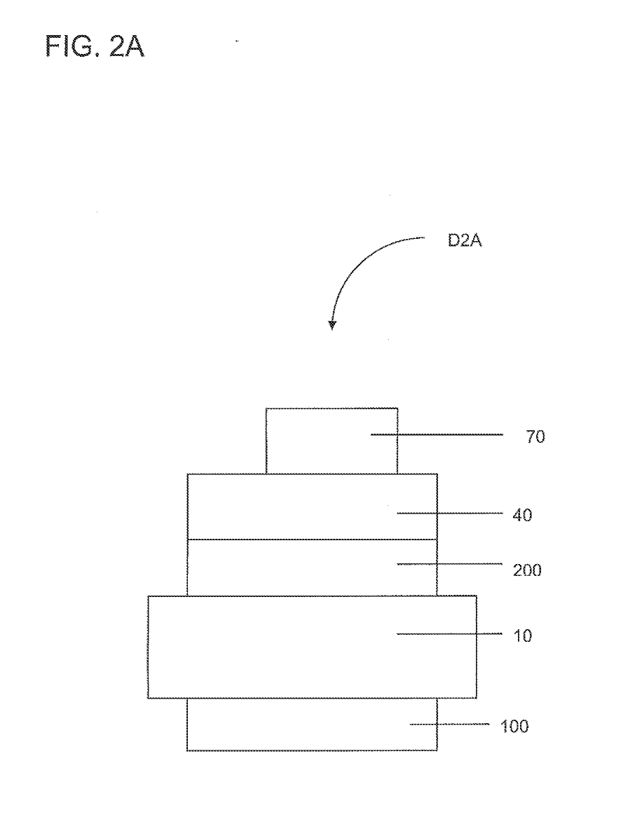

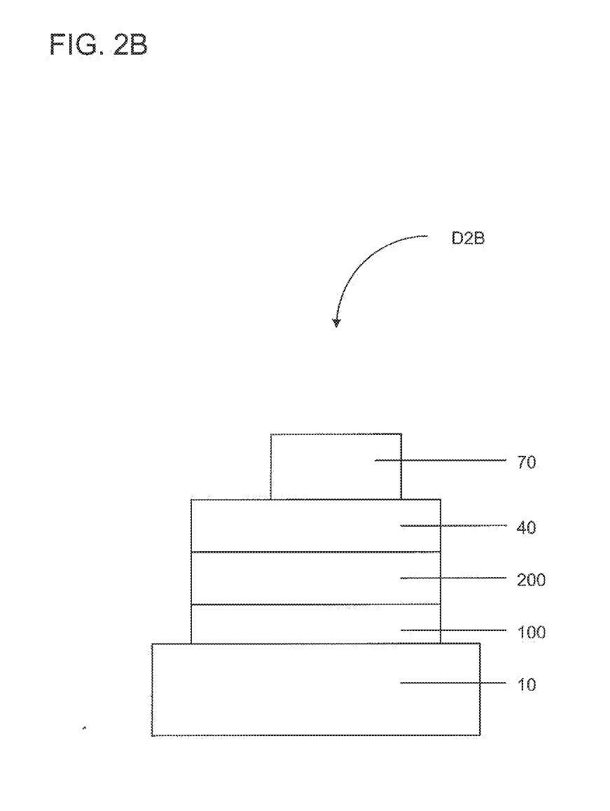

The new devices described herein have one of the structures shown in FIG. 2A and FIG. 2B. In FIG. 2A, device D2A has an enhancement film 100. The enhancement film 100 is on the outer side of and in direct contact with substrate 10. Anode 200 is a single layer A1 or a multilayer structure, as described above. The photoactive layer 40 and cathode 70 are as described above. In this figure, and in all subsequent figures, the other device layers are not shown, but may be present as discussed above. In this figure and in all subsequent figures, the substrate is shown as 10, the photoactive layer is shown as 40 and the cathode is shown as 70.

In FIG. 2B, device D2B has enhancement film 100 on the device side of substrate 10. Enhancement film is in direct contact with substrate 10 and is between the substrate and the anode 200. Anode 200 is a single layer A1 or a multilayer structure, as described above.

In some embodiments, anode 200 is a single layer A1 comprising an alloy of a metal having an electrical conductivity greater than 10⁵ Scm⁻¹ and a real refractive index less than 2.1 in the range of 380 to 780 nm. In some embodiments, anode 200 consists essentially of an alloy of a metal having an electrical conductivity greater than 10⁵ Scm⁻¹ and a real refractive index less than 2.1 in the range of 380 to 780 nm.

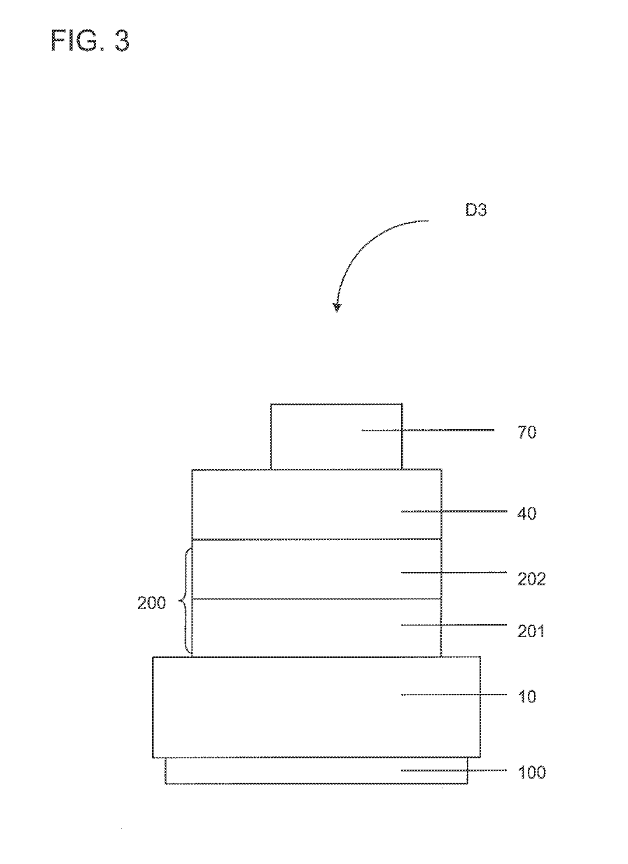

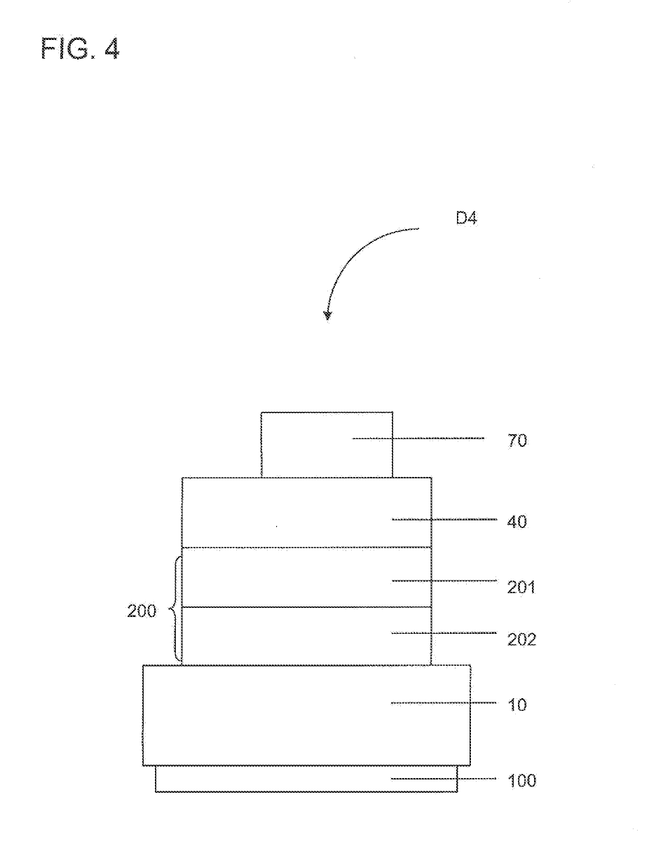

In some embodiments, the anode is a bilayer. This is illustrated schematically in FIGS. 3 and 4. Device D3 in FIG. 3, has an anode 200 with a first layer 201 and a second layer 202. Layer 201 is M1 and layer 202 is M2. In this figure, the enhancement film 100 is shown on the outer side of substrate 10.

Device D4 in FIG. 4, has a bilayer anode 200 with the layers reversed. Layer 202, which is M2, is directly on the substrate 100 and layer 201, which is M1, is over and in direct physical contact with layer 202.

In some embodiments, the anode may have one or ore additional layers including a layer M2, a layer M3, and a layer M4.

When layer M2 is present, it is in direct physical contact with ayer M1 or layer A1.

When layer M3 is present it is adjacent the substrate. By this it is meant that layer M3 on the substrate side of the anode, but not necessarily in direct physical contact with the substrate. In some embodiments, layer M3 is in physical contact with the substrate. In some embodiments, layer M3 is in physical contact with the enhancement film.

When layer M4 is present it is adjacent the photoactive layer. By this it is meant that layer M4 on the photoactive layer side of the anode, but not necessarily in direct physical contact with the photoactive layer. In some embodiments, there is a hole transport layer between layer M4 and the photoactive layer.

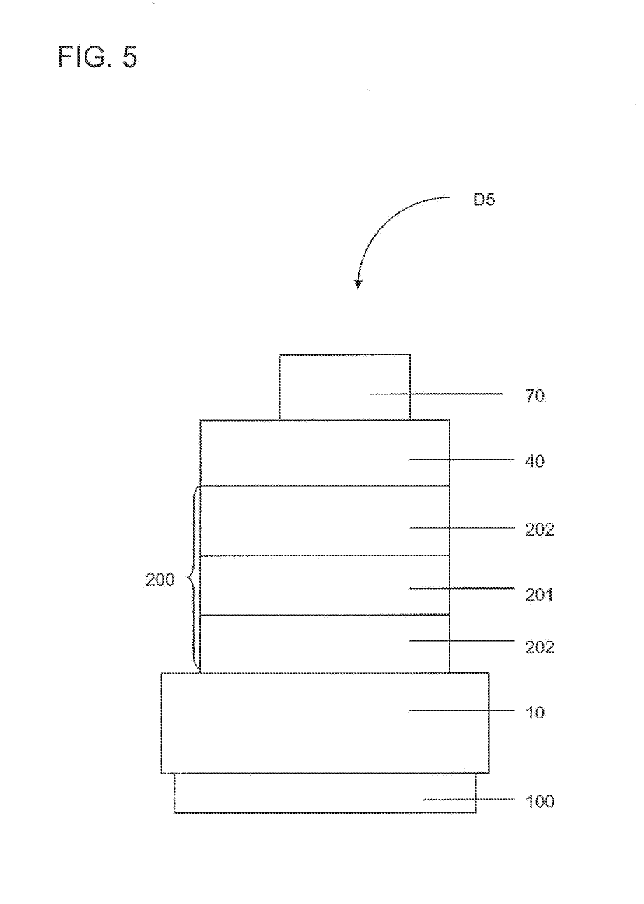

FIGS. 5-13 illustrate embodiments in which the one or more additional layers are present in the anode.

Device D5, in FIG. 5, has an anode 200 with layers 202, 201, and 202, in that order. Layer 202 is M2, layer 201 is M1, and the second 202 layer is M2.

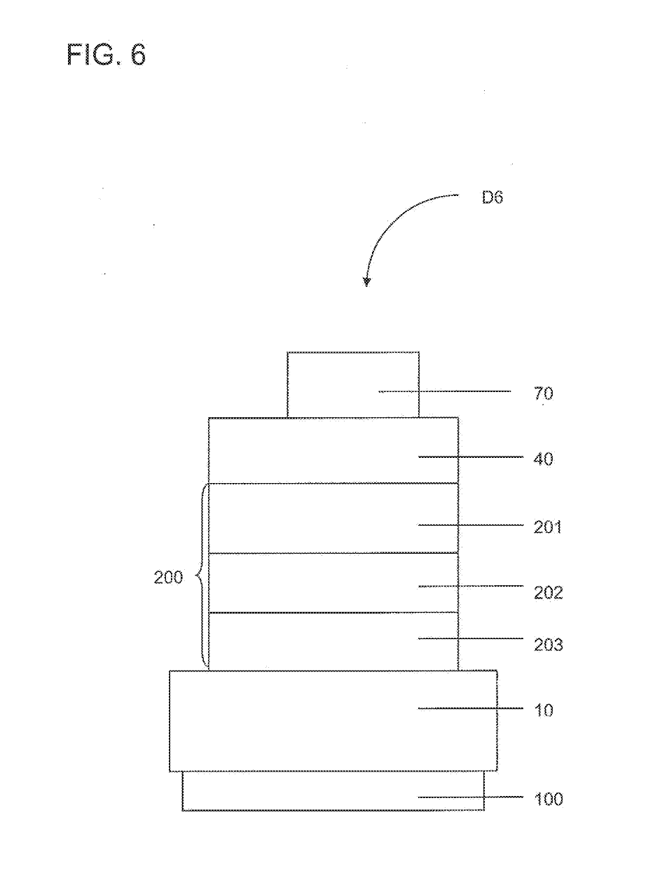

Device D6, in FIG. 6, has an anode 200 with layers 203, 202, and 201, in that order. Layer 203 is M3, layer 202 is M2, and layer 201 is M1.

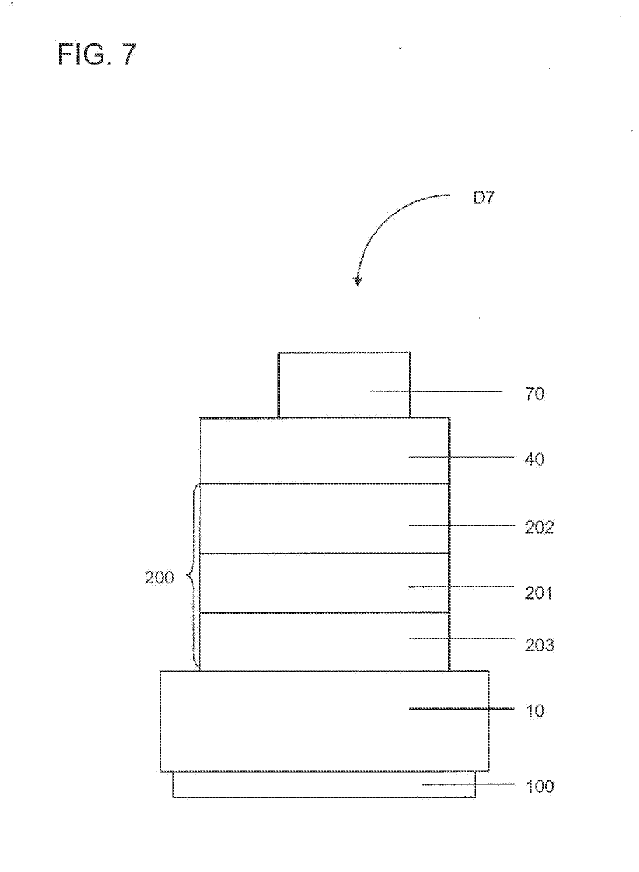

Device D7, in FIG. 7, has an anode 200 with layers 203, 201, and 202, in that order. Layer 203 is M3, layer 201 is M1, and layer 202 is M2.

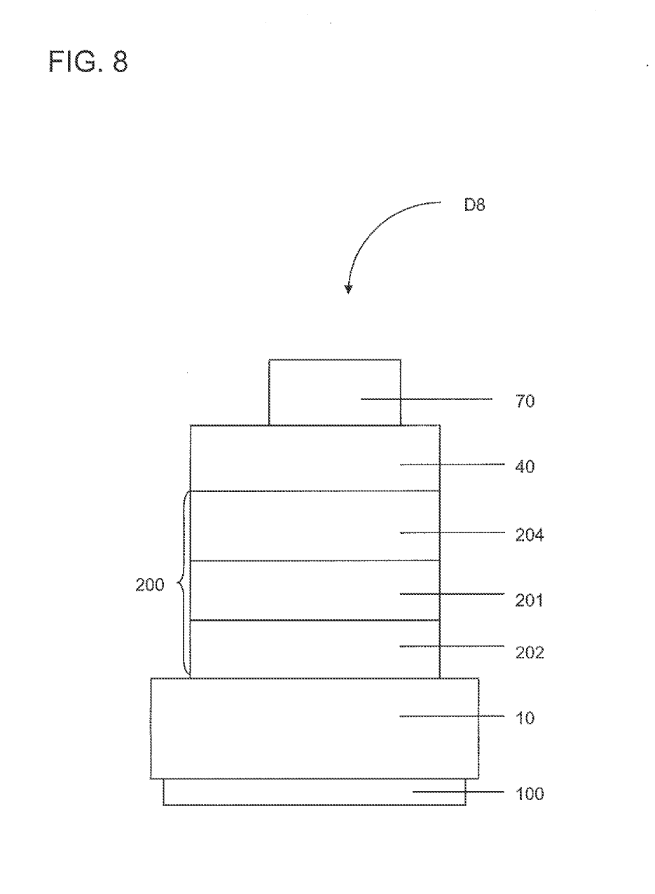

Device D8, in FIG. 8, has an anode 200 with layers 202, 201, and 204 in that order. Layer 202 is M2, layer 201 is M1, and layer 204 is M4.

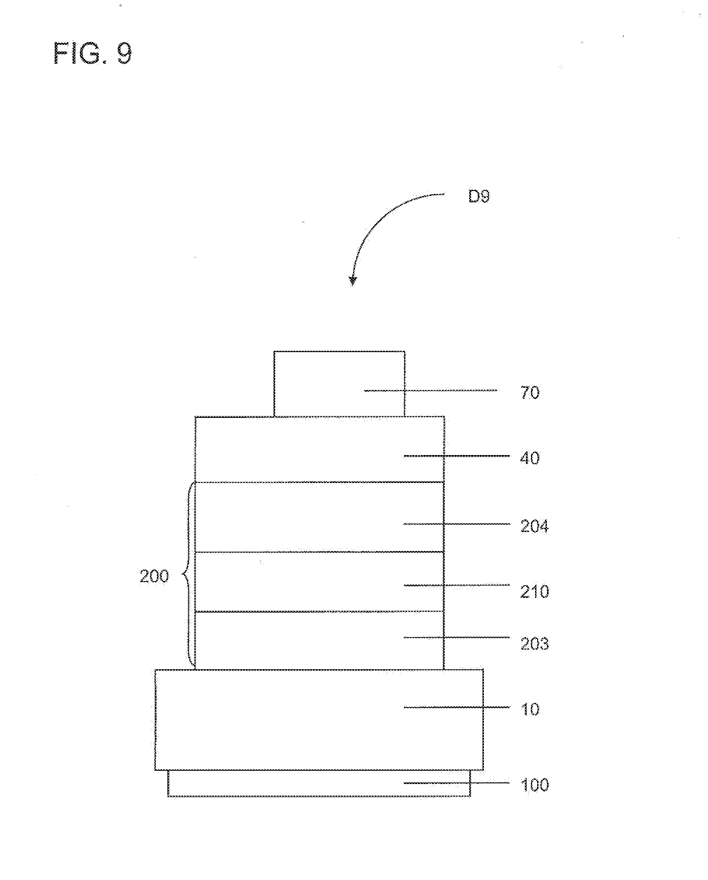

Device D9, in FIG. 9, has an anode 200 with layers 203, 210, and 204 in that order. Layer 203 is M3, layer 210 is A1, and layer 204 is M4.

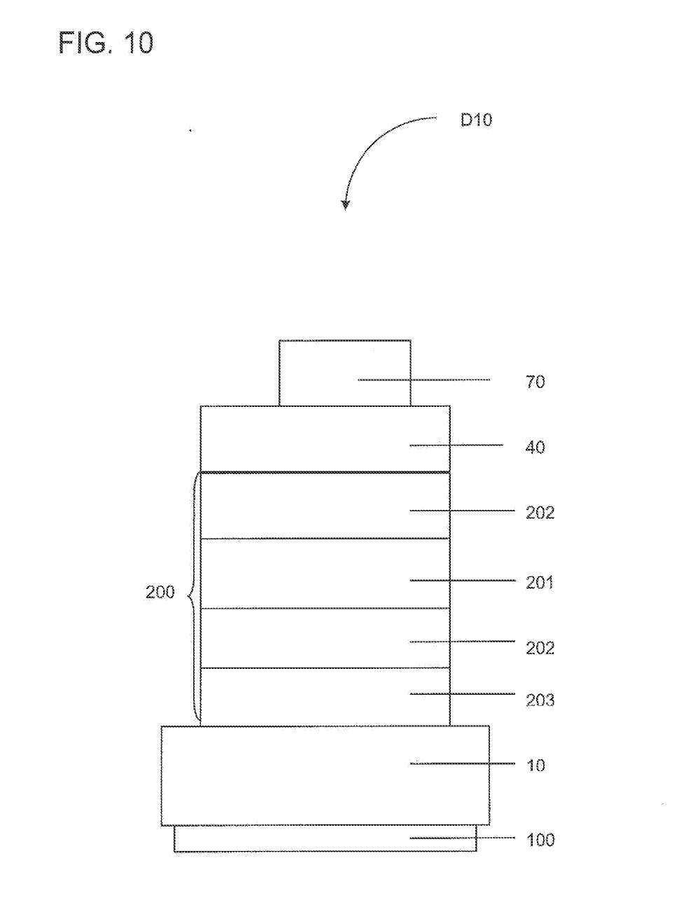

Device D10, in FIG. 10, has an anode 200 with layers 203, 202, 201, and 202 in that order. Layer 203 is M3, layer 202 is M2, layer 201 is M1, and second layer 202 is M2.

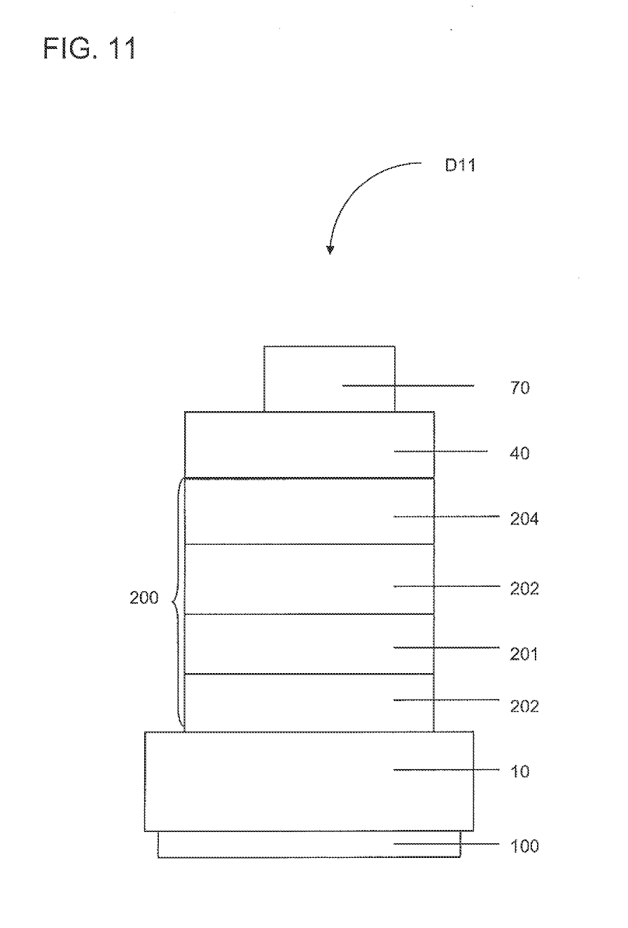

Device D11, in FIG. 11 has an anode 200 with layers 202, 201, 202, and 204 in that order. Layer 202 is M2, layer 201 is M1, the second layer 202 is M2, and layer 204 is M4.

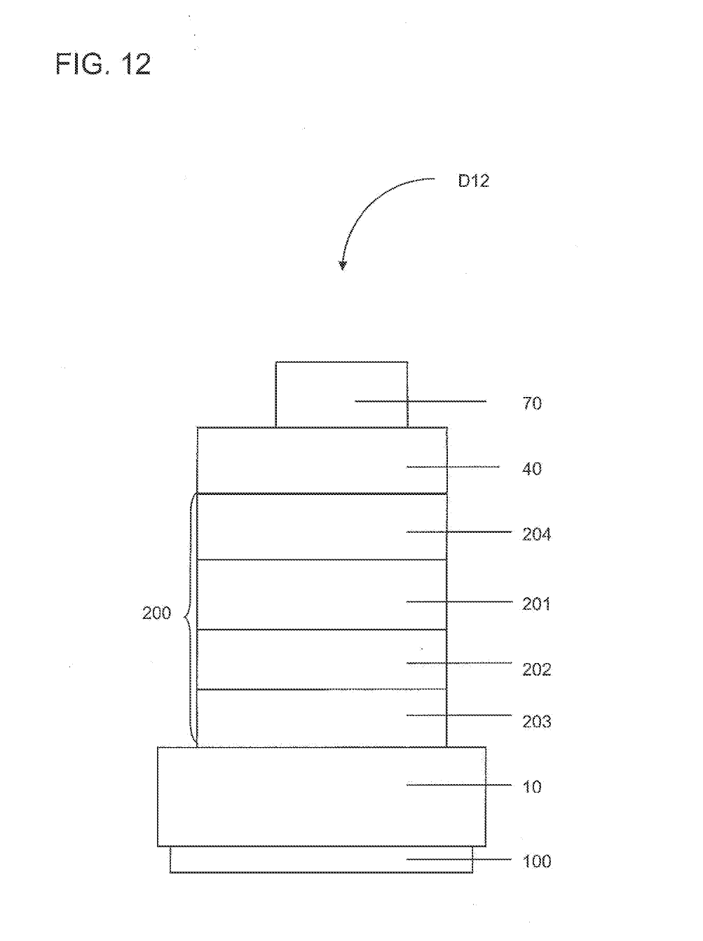

Device D12, in FIG. 12, has an anode 200 with layers 203, 202, 201, and 204 in that order. Layer 203 is M3, layer 202 is M2, layer 201 is M1, and layer 204 is M4.

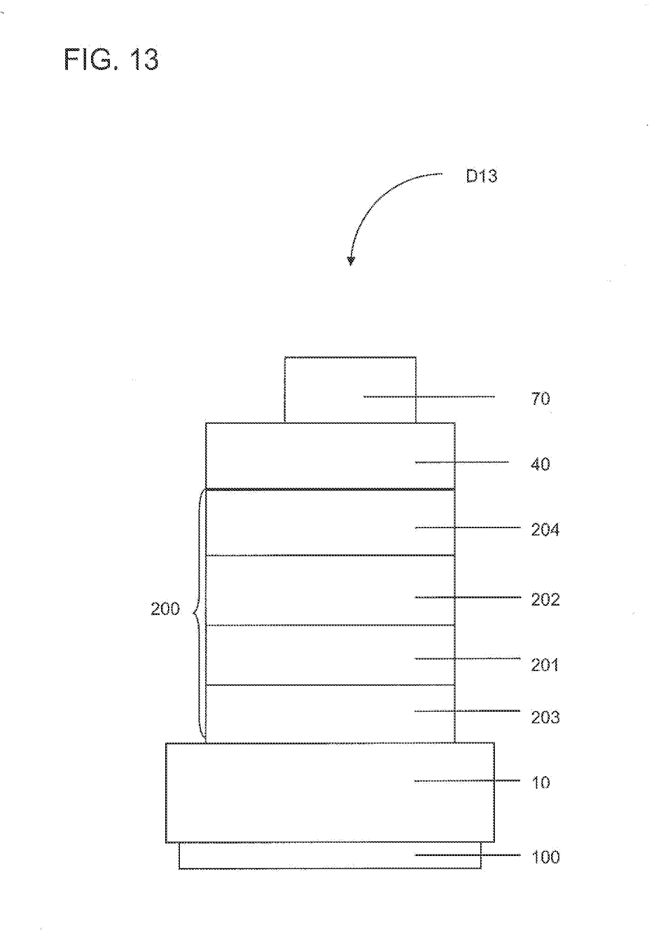

Device D13, in FIG. 13, has an anode 200 with layers 203, 201, 202, and 204 in that order. Layer 203 is M3, layer 201 is M1, layer 202 is M2, and layer 204 is M4.

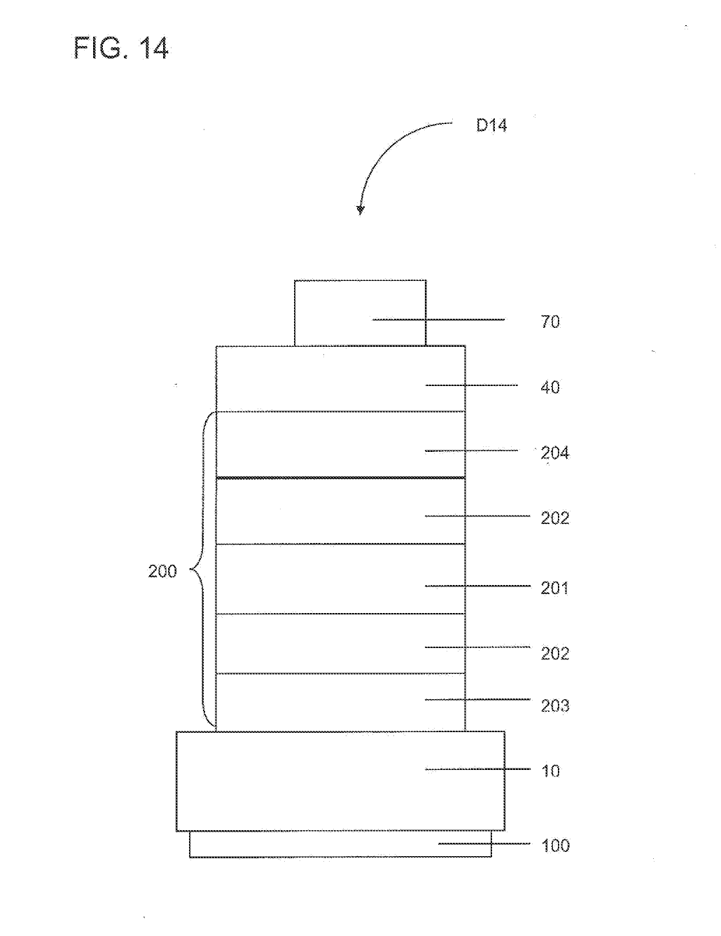

Device D14, in FIG. 14, has an anode 200 with layers 203, 202, 201, 202, and 204, in that order. Layer 203 is M3, layer 202 is M2, layer 201 is M1, the second layer 202 is M2, and layer 204 is M4.

In all of the above devices D3-D14, the enhancement film is shown on the outer side of substrate 10. It will be understood that in any of the above devices D3-D14, the enhancement film could be positioned on the other side of the substrate, between the substrate and anode, as shown in FIG. 2B.

Other anodes with combinations of layers M1 through M4 are also possible.

a. Other Device Layers

The other layers in the device can be made of any materials that are known to be useful in such layers.

The substrate 10 is a base material that can be either rigid or flexible. The substrate may include one or more layers of one or more materials, which can include, but are not limited to, glass, polymer, metal or ceramic materials or combinations thereof. The substrate may or may not include electronic components, circuits, or conductive members.

Examples of hole transport materials for optional layer 30 have been summarized for example, in Kirk-Othmer Encyclopedia of Chemical Technology, Fourth Edition, Vol. 18, p. 837-860, 1996, by Y. Wang. Both hole transporting molecules and polymers can be used. Commonly used hole transporting molecules are: N,N′-diphenyl-N,N′-bis(3-methylphenyl)-[1,1′-biphenyl]-4,4′-diamine (TPD), 1,1-bis[(di-4-tolylamino)phenyl]cyclohexane (TAPC), N,N′-bis(4-methylphenyl)-N,N′-bis(4-ethylphenyl)-[1,1′-(3,3′-dimethyl)biphenyl]-4,4′-diamine (ETPD), tetrakis-(3-methylphenyl)-N,N,N′,N′-2,5-phenylenediamine (PDA), a-phenyl-4-N,N-diphenylaminostyrene (TPS), p-(diethylamino)benzaldehyde diphenylhydrazone (DEH), triphenylamine (TPA), bis[4-(N,N-diethylamino)-2-methylphenyl](4-methylphenyl)methane (MPMP), 1-phenyl-3-[p-(diethylamino)styryl]-5-[p-(diethylamino)phenyl]pyrazoline (PPR or DEASP) 1,2-trans-bis(9H-carbazol-9-yl)cyclobutane (DCZB), N,N,N′,N′-tetrakis(4-methylphenyl)-(1,1′-biphenyl)-4,4′-diamine (TTB), N,N′-bis(naphthalen-1-yl)-N,N′-bis-(phenyl)benzidine (NPB), and porphyrinic compounds, such as copper phthalocyanine. Commonly used hole transporting polymers are polyvinylcarbazole, (phenylmethyl)-polysilane, and polyaniline. It is also possible to obtain hole transporting polymers by doping hole transporting molecules such as those mentioned above into polymers such as polystyrene and polycarbonate. In some cases, triarylamine polymers are used, especially triarylamine-fluorene copolymers. In some cases, the polymers and copolymers are crosslinkable. In some embodiments, the hole transport layer further comprises a p-dopant. In some embodiments, the hole transport layer is doped with a p-dopant. Examples of p-dopants include, but are not limited to, tetrafluorotetracyanoquinodimethane (F4-TCNQ) and perylene-3,4,9,10-tetracarboxylic-3,4,9,10-dianhydride (PTCDA).

Depending upon the application of the device, the photoactive layer 400 can be a light-emitting layer that is activated by an applied voltage (such as in a light-emitting diode or light-emitting electrochemical cell), a layer of material that responds to radiant energy and generates a signal with or without an applied bias voltage (such as in a photodetector). In one embodiment, the electroactive layer comprises an organic electroluminescent (“EL”) material. Any EL material can be used in the devices, including, but not limited to, small molecule organic fluorescent compounds, luminescent metal complexes, conjugated polymers, and mixtures thereof. Examples of fluorescent compounds include, but are not limited to, chrysenes, pyrenes, perylenes, rubrenes, coumarins, anthracenes, thiadiazoles, derivatives thereof, and mixtures thereof. Examples of metal complexes include, but are not limited to, metal chelated oxinoid compounds, such as tris(8-hydroxyquinolato)aluminum (Alq3); cyclometalated iridium and platinum electroluminescent compounds, such as complexes of iridium with phenylpyridine, phenylquinoline, or phenylpyrimidine ligands as disclosed in Petrov et al., U.S. Pat. No. 6,670,645 and Published PCT Applications WO 03/063555 and WO 2004/016710, and organometallic complexes described in, for example, Published PCT Applications WO 03/008424, WO 03/091688, and WO 03/040257, and mixtures thereof. Examples of conjugated polymers include, but are not limited to poly(phenylenevinylenes), polyfluorenes, poly(spirobifluorenes), polythiophenes, poly(p-phenylenes), copolymers thereof, and mixtures thereof.

In some cases the light-emitting materials are deposited as a dopant with a host material to improve processing and/or electronic properties.

Examples of red light-emitting materials include, but are not limited to, complexes of Ir having phenylquinoline or phenylisoquinoline ligands, periflanthenes, fluoranthenes, and perylenes. Red light-emitting materials have been disclosed in, for example, U.S. Pat. No. 6,875,524, and published US application 2005-0158577.

Examples of green light-emitting materials include, but are not limited to, complexes of Ir having phenylpyridine ligands, bis(diarylamino)anthracenes, and polyphenylenevinylene polymers. Green light-emitting materials have been disclosed in, for example, published POT application WO 2007/021117.

Examples of blue light-emitting materials include, but are not limited to, complexes of Ir having phenylpyridine or phenylimidazole ligands, diarylanthracenes, diaminochrysenes, diaminopyrenes, and polyfluorene polymers. Blue light-emitting materials have been disclosed in, for example, U.S. Pat. No. 6,875,524, and published US applications 2007-0292713 and 2007-0063638.

In some embodiments, for lighting applications it is desirable to use electroluminescent materials which have emission from a triplet excited state or mixed singlet-triplet excited state. In some embodiments, the electroluminescent material is an organometallic complex. In some embodiments, the organometallic complex is cyclometallated. By “cyclometallated” it is meant that the complex contains at least one ligand which bonds to the metal in at least two points, forming at least one 5- or 6-membered ring with at least one carbon-metal bond. In some embodiments, the metal is iridium or platinum. In some embodiments, the organometallic complex is electrically neutral and is a tris-cyclometallated complex of iridium having the formula IrL₃ or a bis-cyclometallated complex of iridium having the formula IrL₂Y. In some embodiments, L is a monoanionic bidentate cyclometalating ligand coordinated through a carbon atom and a nitrogen atom. In some embodiments, L is an aryl N-heterocycle, where the aryl is phenyl or napthyl, and the N-heterocycle is pyridine, quinoline, isoquinoline, diazine, pyrrole, pyrazole or imidazole. In some embodiments, Y is a monoanionic bidentate ligand. In some embodiments, L is a phenylpyridine, a phenylquinoline, or a phenylisoquinoline. In some embodiments, Y is a β-dienolate, a diketimine, a picolinate, or an N-alkoxypyrazole. The ligands may be unsubstituted or substituted with F, D, alkyl, perfluororalkyl, alkoxyl, alkylamino, arylamino, CN, silyl, fluoroalkoxyl or aryl groups.

In some embodiments, the light-emitting material is a cyclometalated complex of iridium or platinum. Such materials have been disclosed in, for example, U.S. Pat. No. 6,670,645 and Published PCT Applications WO 03/063555, WO 2004/016710, and WO 03/040257.

Examples of organometallic iridium complexes having red emission color include, but are not limited to compounds R1 through R10 below.

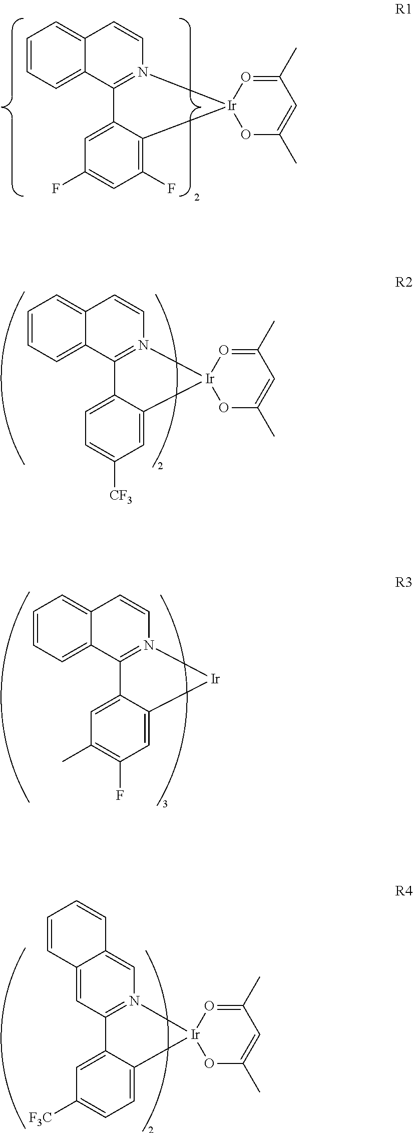

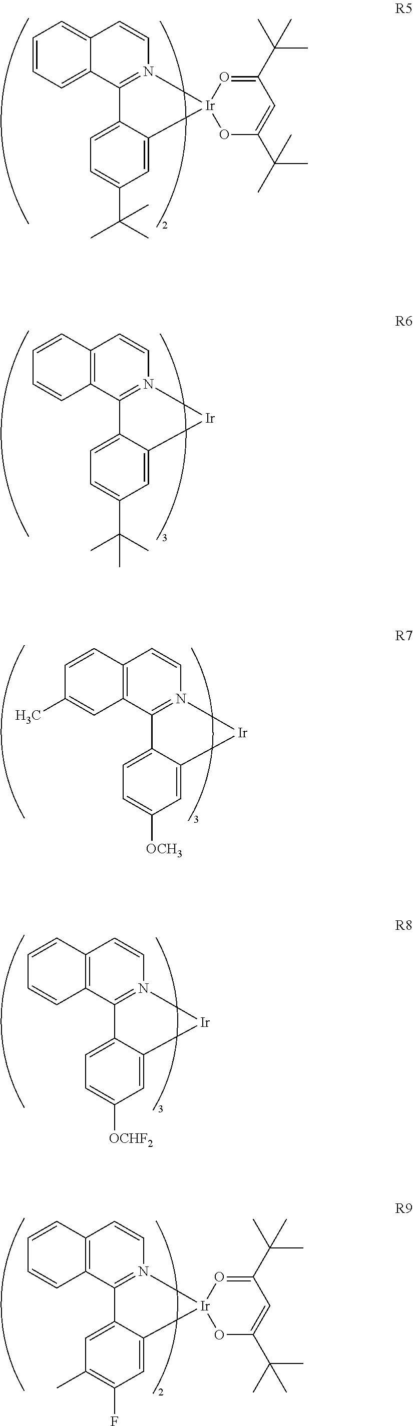

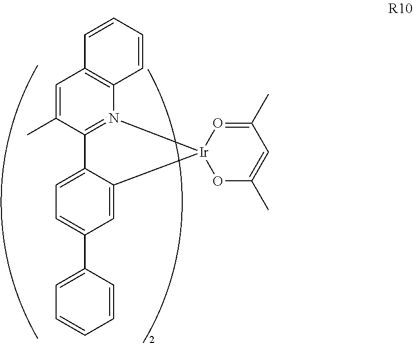

Examples of organometallic iridium complexes having green emission color include, but are not limited to compounds G1 through G10 below.

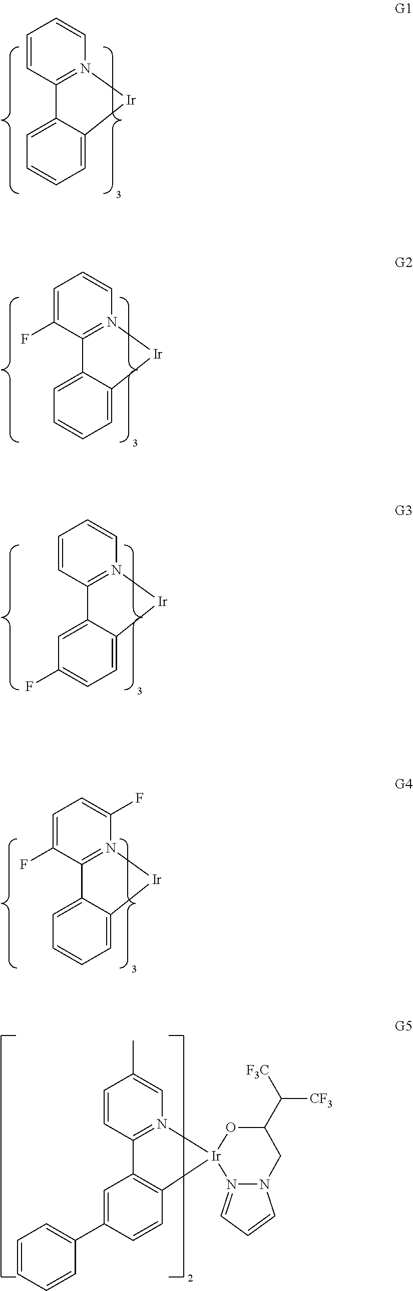

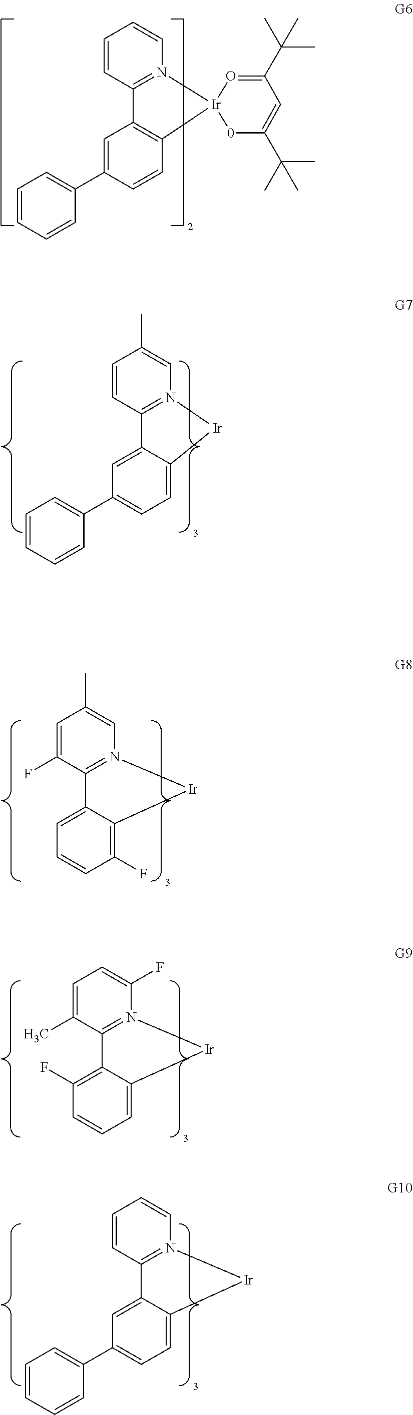

Examples of organometallic iridium complexes having blue emission color include, but are not limited to compounds B1 through B10 below.

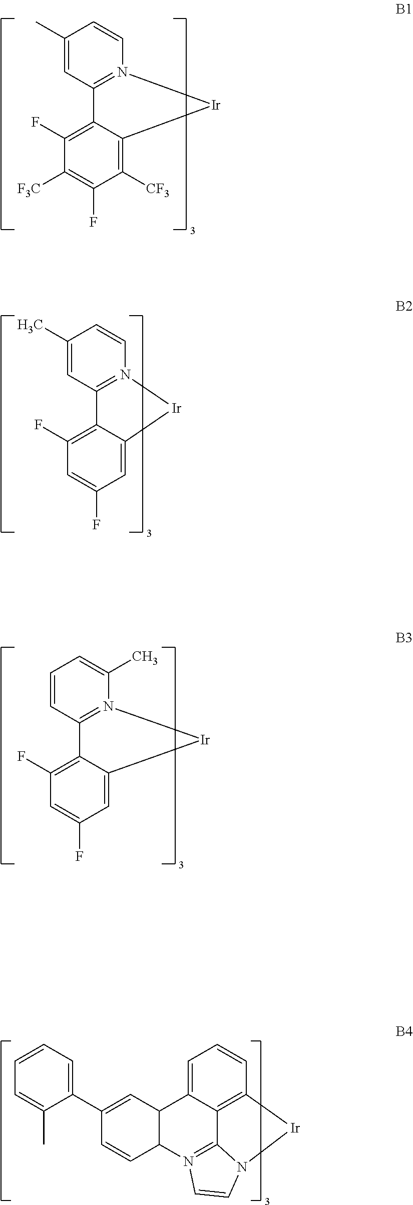

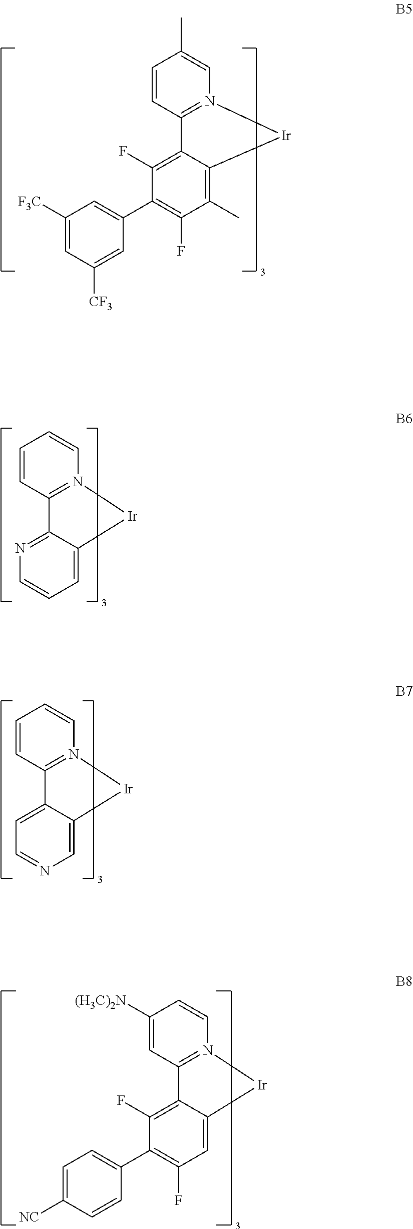

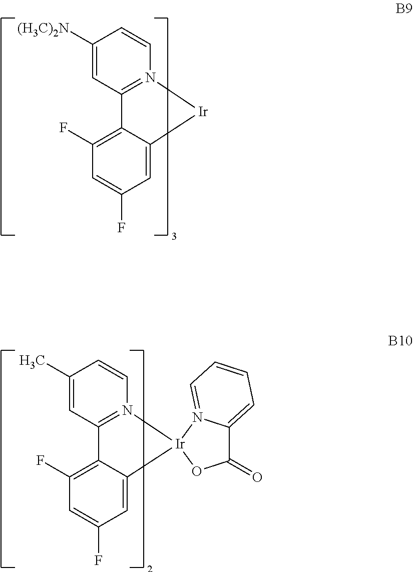

In some embodiments, photoactive layer 40 comprises an electroluminescent material in a host material. In some embodiments, a second host material is also present. Examples of host materials include, but are not limited to, carbazoles, indolocarbazoles, chrysenes, phenanthrenes, triphenylenes, phenanthrolines, triazines, naphthalenes, anthracenes, quinolines, isoquinolines, quinoxalines, phenylpyridines, benzodifurans, metal quinolinate complexes, deuterated analogs thereof, and combinations thereof.

Optional layer 50 can function both to facilitate electron transport, and also serve as a hole injection layer or confinement layer to prevent quenching of the exciton at layer interfaces. Preferably, this layer promotes electron mobility and reduces exciton quenching. Examples of electron transport materials which can be used in the optional electron transport layer 50, include metal chelated oxinoid compounds, including metal quinolate derivatives such as tris(8-hydroxyquinolato)aluminum (AlQ), bis(2-methyl-8-quinolinolato)(p-phenylphenolato) aluminum (BAlq), tetrakis-(8-hydroxyquinolato)hafnium (HfQ) and tetrakis-(8-hydroxyquinolato)zirconium (ZrQ); and azole compounds such as 2-(4-biphenylyl)-5-(4-t-butylphenyl)-1,3,4-oxadiazole (PBD), 3-(4-biphenylyl)-4-phenyl-5-(4-t-butylphenyl)-1,2,4-triazole (TAZ), and 1,3,5-tri(phenyl-2-benzimidazole)benzene (TPBl); quinoxaline derivatives such as 2,3-bis(4-fluorophenyl)quinoxaline; phenanthrolines such as 4,7-diphenyl-1,10-phenanthroline (DPA) and 2,9-dimethyl-4,7-diphenyl-1,10-phenanthroline (DDPA); triazines; fullerenes; and mixtures thereof. In some embodiments, the electron transport material is selected from the group consisting of metal quinolates and phenanthroline derivatives. In some embodiments, the electron transport layer further comprises an n-dopant. N-dopant materials are well known. The n-dopants include, but are not limited to, Group 1 and 2 metals; Group 1 and 2 metal salts, such as LiF, CsF, and Cs₂CO₃: Group 1 and 2 metal organic compounds, such as Li quinolate; and molecular n-dopants, such as leuco dyes, metal complexes, such as W₂(hpp)₄ where hpp=1,3,4,6,7,8-hexahydro-2H-pyrimido-[1,2-a]-pyrimidine and cobaltocene, tetrathianaphthacene, bis(ethylenedithio)tetrathiafulvalene, heterocyclic radicals or diradicals, and the dimers, oligomers, polymers, dispiro compounds and polycycles of heterocyclic radical or diradicals.

The cathode 70, is an electrode that is particularly efficient for injecting electrons or negative charge carriers. The cathode can be any metal or nonmetal having a lower work function than the anode. Materials for the cathode can be selected from alkali metals of Group 1 (e.g., Li, Cs), the Group 2 (alkaline earth) metals, the Group 12 metals, including the rare earth elements and lanthanides, and the actinides. Materials such as aluminum, indium, calcium, barium, samarium and magnesium, as well as combinations, can be used. Li-containing organometallic compounds, LiF, Li₂O, Cs-containing organometallic compounds, CsF, Cs₂O, and Cs₂CO₃ can also be deposited between the organic layer and the cathode layer to lower the operating voltage. This optional layer may be referred to as an electron injection layer 60. In some embodiments, the material deposited for the electron injection layer reacts with the underlying electron transport layer and/or the cathode and does not remain as a measurable layer.

It is known to have other layers in organic electronic devices. The choice of materials for each of the component layers is preferably determined by balancing the positive and negative charges in the emitter layer to provide a device with high electroluminescence efficiency. It is understood that each functional layer can be made up of more than one layer.

In one embodiment, the different layers have the following range of thicknesses: composite anode, 500-5000 Å, in one embodiment 1000-2000 hole transport layer, 50-2000 Å, in one embodiment 200-1000 Å; photoactive layer, 10-2000 Å, in one embodiment 100-1000 Å; electron transport layer, 50-500 Å, in one embodiment 100-300 Å; cathode, 200-10000 Å, in one embodiment 300-5000 Å. The desired ratio of layer thicknesses will depend on the exact nature of the materials used.

The device layers can be formed by any deposition technique, or combinations of techniques, including vapor deposition, liquid deposition, and thermal transfer. Conventional vapor deposition techniques can be used, such as thermal evaporation, chemical vapor deposition, and the like. The organic layers can be applied from solutions or dispersions in suitable solvents, using conventional coating or printing techniques, including but not limited to spin-coating, dip-coating, roll-to-roll techniques, ink-jet printing, continuous nozzle printing, screen-printing, gravure printing and the like.

For liquid deposition methods, a suitable solvent for a particular compound or related class of compounds can be readily determined by one skilled in the art. For some applications, it is desirable that the compounds be dissolved in non-aqueous solvents. Such non-aqueous solvents can be relatively polar, such as C₁ to C₂₀ alcohols, ethers, and acid esters, or can be relatively non-polar such as C₁ to C₁₂ alkanes or aromatics such as toluene, xylenes, trifluorotoluene and the like. Other suitable liquids for use in making the liquid composition, either as a solution or dispersion as described herein, comprising the new compounds, includes, but not limited to, chlorinated hydrocarbons (such as methylene chloride, chloroform, chlorobenzene), aromatic hydrocarbons (such as substituted and non-substituted toluenes and xylenes), including trifluorotoluene), polar solvents (such as tetrahydrofuran (THP), N-methylpyrrolidone) esters (such as ethylacetate) alcohols (isopropanol), keytones (cyclopentatone) and mixtures thereof. Suitable solvents for electrolurninescent materials have been described in, for example, published POT application WO 2007/145979.

In some embodiments, following deposition of the composite anode, as described above, the device is fabricated by liquid deposition of the hole transport layer and the photoactive layer, and by vapor deposition of the electron transport layer, an electron injection layer and the cathode.

It is understood that the efficiency of devices made with the new compositions described herein, can be further improved by optimizing the other layers in the device. For example, more efficient cathodes such as Ca, Ba or LiF can be used. Shaped substrates and novel hole transport materials that result in a reduction in operating voltage or increase quantum efficiency are also applicable. Additional layers can also be added to tailor the energy levels of the various layers and facilitate electroluminescence.

In one embodiment, the device has the following structure, in order: enhancement film, substrate, anode, hole transport layer, photoactive layer, electron transport layer, electron injection layer, cathode.

Although methods and materials similar or equivalent to those described herein can be used in the practice or testing of the present invention, suitable methods and materials are described below. In addition, the materials, methods, and examples are illustrative only and not intended to be limiting. All publications, patent applications, patents, and other references mentioned herein are incorporated by reference in their entirety.

### EXAMPLES

The concepts described herein will be further described in the following examples, which do not limit the scope of the invention described in the claims.

### Materials

Compound 1 is made from an aqueous dispersion of an electrically conductive polymer and a polymeric fluorinated sulfonic acid. Such materials have been described in, for example, published U.S. patent applications US 2004/0102577, US 2004/0127637, and US 2005/0205860 and published POT application WO 2009/018009.
Compound 2 is an N-aryl-indolocarbazole. Such materials have been described in, for example, published US patent application US 2009/0302742.
Compound 3 is a blue-emitting tris cyclometallated iridium complex.
Compound 4 is a metal guinolate complex.
Compound 5 is a triarylamine polymer. Such materials have been described in, for example, published POT application WO 2009/067419.
Compound 6 is a blue-emitting tris cyclometallated iridium complex.
Compound 7 is a green-emitting tris cyclometallated iridium complex.
Compound 8 is a red-emitting bis cyclometallated iridium acetylacetonate complex.
Compound 9 is a carbazole derivative.
Compound 10 is an N-aryl-indolocarbazole.
Compound 11 is a phenanthroline derivative.
Compound 12 is shown below. Such materials have been described in, for example, copending application [UC1006].

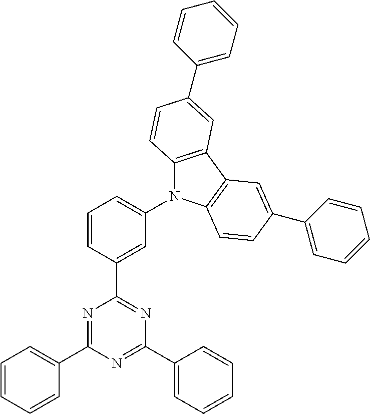 [SMILES: c1ccc(-c2ccc3c(c2)c2cc(-c4ccccc4)ccc2n3-c2cccc(-c3nc(-c4ccccc4)nc(-c4ccccc4)n3)c2)cc1]

Compound 13 is shown below. Such materials have been described in, for example, copending application [UC1006].

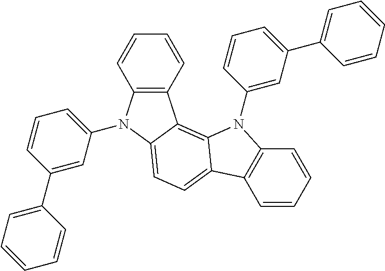 [SMILES: c1ccc(-c2cccc(-n3c4ccccc4c4c3ccc3c5ccccc5n(-c5cccc(-c6ccccc6)c5)c34)c2)cc1]

Compound 14 is shown below. Such materials have been described in, for example, published US application 2010-1087977.

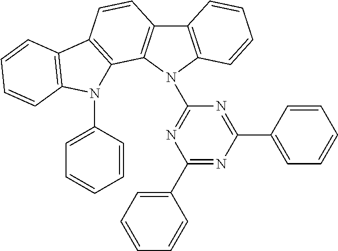 [SMILES: c1ccc(-c2nc(-c3ccccc3)nc(-n3c4ccccc4c4ccc5c6ccccc6n(-c6ccccc6)c5c43)n2)cc1]

Compound 15 is shown below. Such materials have been described in, for example, U.S. Pat. No. 7,023,013.

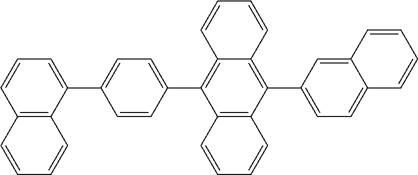 [SMILES: c1ccc2cc(-c3c4ccccc4c(-c4ccc(-c5cccc6ccccc56)cc4)c4ccccc34)ccc2c1]

DPA is 4,7-diphenyl-1,10-phenanthroline
TAPC is shown below.

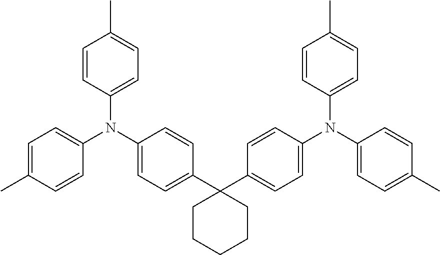

### Example 1

This example illustrates the formation of enhancement films.

The enhancement films comprised a polymeric matrix having particulate material dispersed therein. The polymeric material was a polysiloxane, Sylgard® 184 silicone elastomer (Dow Corning, Midland, Mich.). The particulate material was a nanopowder of ZrO₂ having a particle size less than 100 nm (Sigma-Aldrich, St. Louis, Mo.).

Enhancement films were made by dispersing the ZrO₂ nanopowder in the Sylgard, cured with 10 wt % Sylgard 184 curing agent, and casting into films of various thickness onto a glass substrate.

Enhancement film 1 had 2 wt % ZrO₂ and a film thickness of 1000 microns.

Enhancement film 2 had 4 wt % ZrO₂ and a film thickness of 1250 microns.

### Examples 2 and 3 and Comparative Examples A and B

These examples illustrate the performance of devices having the architecture described herein.

Examples 2 and 3 had the following device layers, in the order listed:
enhancement film
substrate=glass
anode=Cr (0.7 nm)/Ag (15 nm)
hole injection layer=Compound 1 (50 nm)
hole transport layer=TAPC (20 nm)
photoactive layer=6% by weight of Compound 3 in Compound 2 (53 nm)
electron transport layer=Compound 4 (10 nm, as applied)
electron injection layer=CsF (1 nm)
cathode=Al (100 nm)
Example 2 had enhancement film 1.

Example 3 had enhancement film 2.

Comparative Example A had an anode of ITO (120 nm) and no enhancement film.

Comparative Example B had the same anode as Example 2, but with no enhancement film.

The devices were prepared by deposing the layers on the side of the glass substrate which did not have the enhancement film.

Compound 1 was deposited by spin coating from an aqueous dispersion. All other layers were applied by evaporative deposition.

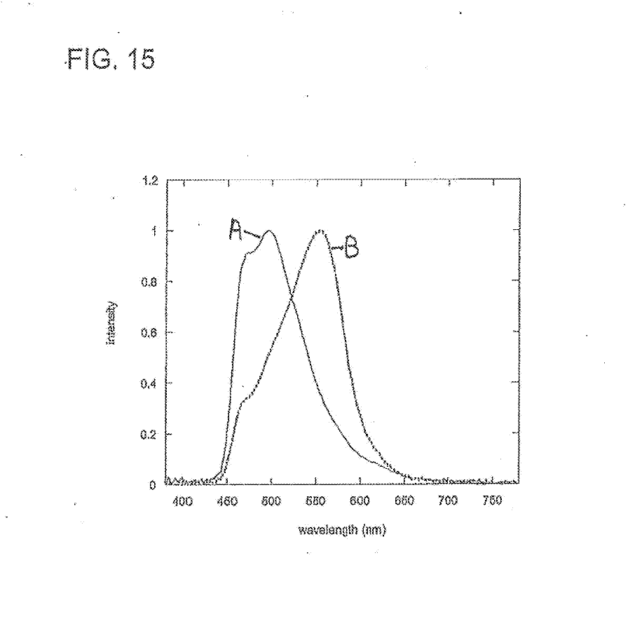

The electroluminescence spectra for Comparative Examples A and B are shown in FIG. 15. The spectrum for Comparative Example A, line A, has a dominant peak at 495 nm in the blue portion of the spectrum. The intensity at the red portion is very weak. The spectrum for Comparative Example B, line B, has a dominant peak at 556 nm in the red portion of the spectrum, but blue part of the spectrum is relatively weak. Thus, it can be seen that replacing an ITO anode with a bilayer anode increases emission from the red part of the spectrum while sacrificing emission from the blue.

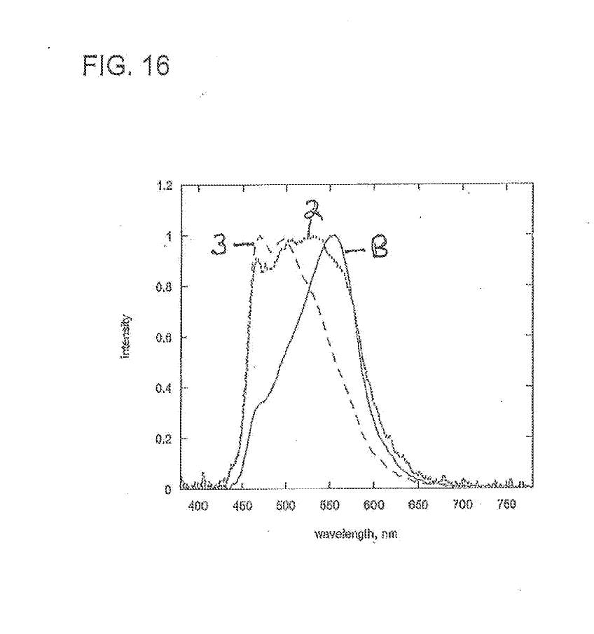

The electroluminescence spectra of Examples 2 and 3 are shown in FIG. 16, line 2 and line 3, respectively. The spectrum from Comparative Example B is included for reference. It can be seen that in Example 2, line 2, the blue portion of the spectrum is enhanced relative to Comparative Example B, while the enhanced red peak of Comparative Example B is maintained. It can be further seen with Example 3, line 3, that the blue portion of the spectrum can be further enhanced by using an enhancement film with higher ZrO₂ loading. Therefore, the white spectrum can be tuned to the exact desired color by fine adjustment of the thickness of the anode layers and the particle concentration and film thickness of the enhancement film.

### Examples 4 and 5 and Comparative Examples C and D

These examples illustrate the performance of devices having the architecture described herein.

Examples 4 and 5 had the following device layers, in the order listed:
enhancement film
substrate=glass
anode=Cr (0.7 nm)/Ag (15 nm)
hole injection layer=Compound 1 (50 nm)
hole transport layer=Compound 5 (20 nm)
photoactive layer=Compound 8, Compound 7, Compound 6, Compound 9 and Compound 10 in weight ratio of 0.7:0.13:15:72:12 (60 nm)
electron transport layer=Compound 11 (10 nm)
electron injection layer=CsF (1 nm, as deposited) cathode=Al (100 nm)

Comparative Example C had an anode of ITO (120 nm) and no enhancement film.

Comparative Example D, had the same anode as Example 4, but with no enhancement film.

The devices were prepared by depositing the layers on the side of the glass substrate which did not have the enhancement film.

Compound 1 was deposited by spin coating from an aqueous dispersion. Compound 5 and the photoactive layer were deposited by spin coating from organic solvents. All other layers were applied by evaporative deposition.

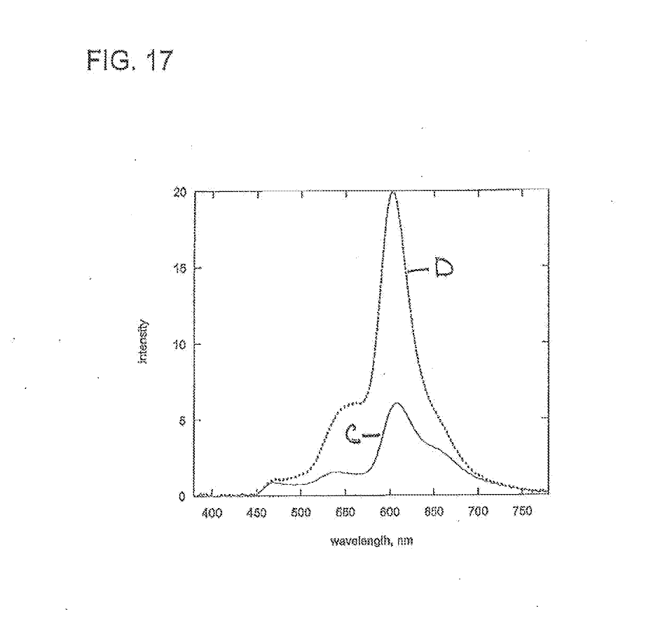

The electroluminescence spectra for Comparative Examples C and D are shown in FIG. 17. The spectrum for Comparative Example D, line D shows enhancement in the red portion compared to Comparative Example C, line C. Thus, it can be seen that replacing an ITO anode with a bilayer anode increases emission from the red part of the spectrum while sacrificing emission from the blue.

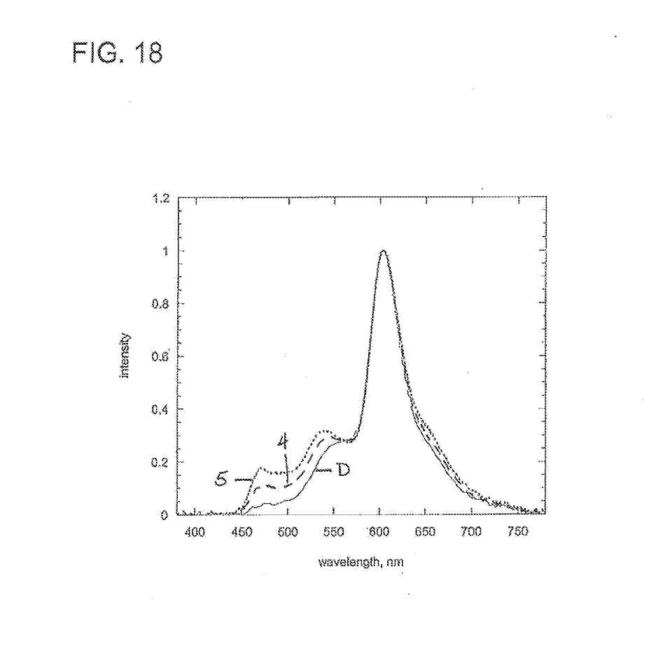

The electroluminescence spectra of Examples 4 and 5 are shown in FIG. 18, lines 4 and 5. The spectrum from Comparative Example D, line D, is included for reference. It can be seen that in the spectrum from Example 4, line 4, the blue portion of the spectrum is enhanced relative to Comparative Example D, line D. It can be further seen that in the spectrum from Example 5, with line 5, the blue portion of the spectrum is further enhanced when the enhancement film has a higher ZrO₂ loading. Therefore, the white spectrum can be tuned to the exact desired color by fine adjustment of the thickness of the anode layers and the particle concentration and film thickness of the enhancement film.

### Example 6

This example illustrates another device having the architecture described herein.

The photoactive layer has materials with red, green, and blue emission colors. The materials are R3, G3, and B1, as shown above, and which can be made according to the procedures in U.S. Pat. No. 6,670,645 and Dalton Trans., 2005, 1583-1590.

The device has the following layers, in the order listed:
substrate=glass
enhancement film 1
anode=Cr (0.7 nm)/Ag (15 nm)/ITO (20 nm)
hole injection layer=Compound 1 (50 nm)
hole transport layer=TAPC (20 nm)
photoactive layer=R3, G3, B1, Compound 13, and Compound 12, in a 0.7:0.13:15:72:12 weight ratio (60 nm)
electron transport layer=DPA
electron injection layer=CsF (1 nm, as deposied)
cathode=Al (100 nm)

The device can be prepared by depositing the layers on the glass substrate which over the enhancement film. Compound 1 can be deposited by spin coating from an aqueous dispersion. All other layers can be applied by evaporative deposition.

### Example 7

This example illustrates another device having the architecture described herein.

The photoactive layer has materials with red, green, and blue emission colors. The materials are R3, G3, and B1, as shown above, and which can be made according to the procedures in U.S. Pat. No. 6,670,645 and Dalton Trans., 2005, 1583-1590. R3 and G3 are mixed in a first photoactive layer; and B1 is located in a second, separate photoactive layer

The device has the following layers, in the order listed:
enhancement film 1
substrate=glass
anode=Cr (0.7 nm)/Ag (15 nm)/ITO (20 nm)
hole injection layer=Compound 1 (50 nm)
hole transport layer=TAPC (20 nm)
photoactive layer 1=R3, G3, Compound 14, and Compound 12, in a 1:15:63:21 weight ratio (30 nm)
photoactive layer 2=B1 and Compound 15, in a 8:92 weight ratio (30 nm)
electron transport layer=DPA
electron injection layer=CsF (1 nm, as deposited)
cathode=Al (100 nm)

The device can be prepared by depositing the layers on the glass substrate which is over the enhancement film. Compound 1 can be deposited by spin coating from an aqueous dispersion. All other layers can be applied by evaporative deposition.

Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination. Further, reference to values stated in ranges include each and every value within that range.

What is claimed is:

1. An organic electronic device comprising a light-transmitting substrate, an enhancement film in direct contact with the substrate, an anode, a photoactive layer, and a cathode, wherein the anode comprises one of (a) a single layer A1 and (b) a multilayer, wherein the single layer A1 comprises an alloy of a first metal having an electrical conductivity greater than 10⁵ Scm⁻¹ and a real refractive index less than 2.1 in the range of 380 to 780 nm; and the multilayer comprises:
(a) layer M1 having a first thickness and comprising the first metal; and
(b) layer M2 having a second thickness and comprising a material selected from the group consisting of a second metal, an alloy of the second metal, and a mixed metal oxide, where the second metal has an electrical conductivity less than 10⁵ Scm⁻¹;
wherein layer M1 is in physical contact with layer M2 and the first thickness is greater than the second thickness.

2. The device of claim 1, wherein the enhancement film is on a first surface of the substrate and the anode is on a second surface of the substrate which is opposite the first surface.

3. The device of claim 1, wherein the enhancement film is between the substrate and the anode.

4. The device of claim 1, wherein the enhancement film comprises a polymeric matrix having particulate material dispersed therein.

5. The device of claim 4, wherein the polymeric matrix is selected from the group consisting of polymethylmethacrylate films, polycarbonate films, and polysiloxane films.

6. The device of claim 4, wherein the particulate material has a refractive index greater than 1.9, as measured at 632.8 nm.

7. The device of claim 4, wherein the particulate material is selected from the group consisting of TiO₂, ZrO₂, AlN, BaTiO₃, and mixtures thereof.

8. The device of claim 1, wherein the enhancement film has a thickness in the range of 0.5 microns to 1.0 mm.

9. The device of claim 1, wherein the first metal is selected from the group consisting of copper, silver, and gold.

10. The device of claim 1, wherein A1 comprises an alloy selected from the group consisting of silver/gold, silver/gold/copper, gold/nickel, gold/palladium, silver/germanium, silver/copper, silver/palladium, silver/nickel, and silver/titanium.

11. The device of claim 1, wherein layer M1 has a thickness of 5-50 nm and layer M2 has a thickness of 0.1-5 nm.

12. The device of claim 1, wherein the second metal is selected from the group consisting of chromium, nickel, palladium, titanium, and germanium.

13. The device of claim 1, wherein layer M2 comprises a material selected from the group consisting of chromium, nickel, palladium, titanium, germanium, and indium tin oxide.

14. The device of claim 1, further comprising a second layer M2 having a thickness which is less than the first thickness.

15. The device of claim 1, further comprising a layer M3 comprising indium-tin-oxide, indium-zinc-oxide, aluminum-tin-oxide, aluminum-zinc-oxide, or zirconium-tin-oxide.

16. The device of claim 1, further comprising a layer M4 comprising an organic hole injection material.

17. The composite electrode of claim 16, wherein the hole injection material comprises hexaazatriphenylene hexacarbonitrile or a conducting polymer doped with a colloid-forming polymeric sulfonic acid.
